(19) United States
(12) Patent Application Publication
(10) Pub. No.: US 2017/0275950 A1
(43) Pub. Date: Sep. 28, 2017

(54) DOWNHOLE TOOLS HAVING VOLUMES OF HARD MATERIAL INCLUDING QUENCHED CARBON AND RELATED METHODS

(71) Applicant: Baker Hughes Incorporated, Houston, TX (US)

(72) Inventors: Reed W. Spencer, Spring, TX (US); John Abhishek Raj Bomidi, Spring, TX (US); Aaron J. Dick, Houston, TX (US)

(21) Appl. No.: 15/077,780

(22) Filed: Mar. 22, 2016

(51) Int. Cl. E21B 10/567; C23C 14/06; E21B 43/12; E21B 10/22; E21B 4/02

(52) U.S. Cl. CPC E21B 10/567; E21B 10/22; E21B 4/02; E21B 43/128; C23C 14/0605

(57) ABSTRACT

Methods of forming a volume of hard material on a component of a downhole tool include depositing a film of amorphous carbon on a substrate, irradiating the film of amorphous carbon to form a liquid carbon in an undercooled state, and quenching the liquid carbon to form a layer of quenched carbon on the substrate. A downhole tool comprises a component and a volume of hard material comprising quenched carbon disposed on a surface of the component. Additional downhole tools comprise a component and a polycrystalline compact comprising quenched carbon grains disposed on a surface of the component.

### TECHNICAL FIELD

The present disclosure relates generally to methods of forming volumes of hard material on components of downhole tools subject to wear or erosion, and to components and tools formed by such methods.

### BACKGROUND

Downhole tools are used for various purposes during subterranean wellbore formation, completion, and production. For example, drill bits and reamers are downhole tools used for forming and/or enlarging a wellbore as they are rotated and advanced into the subterranean formation. The drill bit is coupled, either directly or indirectly, to an end of a drill string. The drill bit may be rotated within the wellbore by rotating the drill string from the surface of the formation, or the drill bit may be rotated by coupling the drill bit to a downhole motor, which is also coupled to the drill string and disposed proximate the bottom of the wellbore. The downhole motor may comprise, for example, a hydraulic Moineau-type motor having a shaft to which the drill bit is mounted, that may be caused to rotate by pumping drilling fluid (e.g., drilling mud) from the surface of the formation down through the center of the drill string, through the hydraulic motor, out from the nozzles in the drill bit, and back up to the surface of the formation through the annular space between the outer surface of the formation within the wellbore. Downhole tools used for wellbore completion and production processes include, for example, tools for perforating casing and liner, packers, pumps, valves, etc.

Downhole tools are often subjected to wear due to abrasion and erosion. As a result, coatings have been developed for components of such downhole tools that are intended to improve the resistance of the components to wear and/or erosion. For example, such coatings include hardfacing compositions including hard particles embedded in a matrix material, diamond coatings, and coatings of diamond-like material.

### BRIEF SUMMARY

In some embodiments of the present disclosure, a method of forming a volume of hard material on a component of a downhole tool includes depositing a film of amorphous carbon on a substrate, wherein the substrate comprises a component of a downhole tool, irradiating the film of amorphous carbon to form liquid carbon in an undercooled state, and quenching the liquid carbon to faun a layer of quenched carbon on the substrate.

In additional embodiments, a downhole tool comprises a component of the downhole tool, and a volume of hard material comprising quenched carbon disposed on a surface of the component.

In yet further embodiments, a downhole tool comprises a component of the downhole tool, and a polycrystalline compact comprising quenched carbon grains disposed on a surface of the component.

### BRIEF DESCRIPTION OF THE DRAWINGS

While the specification concludes with claims particularly pointing out and distinctly claiming what are regarded as embodiments of the present disclosure, various features and advantages of embodiments of the disclosure may be more readily ascertained from the following description of example embodiments of the disclosure when read in conjunction with the accompanying drawings, in which:

FIGS. 1A through 1E illustrate a method of forming a layer of quenched carbon on a component of a downhole tool;

FIG. 2 is a simplified drawing of a microstructure of a polycrystalline diamond compact including grains of diamond formed by the methods of FIGS. 1A and 1E;

FIG. 3 is a simplified drawing of a microstructure of a layer including grains of diamond formed by the method of FIGS. 1A through 1E;

FIG. 4 illustrates a roller cone bit according to embodiments of the present disclosure;

FIGS. 5 through 7 are cross-sectional views of bearing assemblies that may be employed in a roller cone bit like that shown in FIG. 4;

FIG. 8 illustrates a leading end of a fixed-cutter bit according to embodiments of the present disclosure;

FIG. 9 is a cross-sectional view of a bearing assembly of a downhole motor according to embodiments of the present disclosure;

FIG. 10 is a cross-sectional view of a power section of a downhole motor according to embodiments of the present disclosure;

FIGS. 11A and 11B are cross-sectional views of a pump assembly of an electric submersible pump according to embodiments of the present disclosure;

FIG. 12 is a cross-sectional view of a seal assembly of an electric submersible pump according to embodiments of the present disclosure;

FIG. 13 is a cross-sectional view of a portion of a drill string according to embodiments of the present disclosure; and

FIG. 14 is a partial, cross-sectional view of a mud pulser according to embodiments of the present disclosure.

### DETAILED DESCRIPTION

As used herein, the term “and/or” means and includes any and all combinations of one or more of the associated listed items.

The illustrations presented herein are not meant to be actual views of any particular component, device, or system, but are merely idealized representations that are employed to describe embodiments of the disclosure. Elements common between figures may retain the same numerical designation.

Embodiments of the present disclosure relate to methods of forming a wear-resistant volume of hard material on a downhole tool. In some embodiments, the volume of hard material may comprise quenched carbon. As used herein, the term “quenched carbon” means and includes a solid state of carbon having between about 70% and about 85% sp³ bonded carbon with a remainder of sp² bonded carbon. The designation sp³ refers to the tetrahedral bond of carbon in diamond, while the designation sp² refers to the type of bond in graphite. The quenched carbon may have an average effective atomic radius of about 0.075 nm. The quenched carbon may have a greater mass density and a shorter carbon-to-carbon bond length than amorphous carbon from which the quenched carbon is formed.

Quenched carbon may be formed from amorphous carbon that is laser irradiated and melted, and rapidly quenched from an undercooled state to convert the amorphous carbon into quenched carbon as described, for example, in J. Narayan et al., “Research Update: Direct Conversion of Amorphous Carbon into Diamond at Ambient Pressures and Temperatures in Air,” APL Materials 3, 100702 (2015); and J. Narayan et al., “Novel Phase of Carbon, Ferromagnetism, and Conversion into Diamond, J. Appl. Phys. 118, 215303 (2015) (hereinafter collectively referred to as “the Narayan references”), the entire disclosure of each of which is incorporated herein by this reference. As used herein, the term “undercooling” means and includes a process of lowering the temperature of a material in liquid form below its melting or freezing point without the liquid becoming a solid, also referred to as “supercooling” in the art. As used herein, the term “undercooled state” means and includes the state of a material in liquid form below its melting or freezing point.

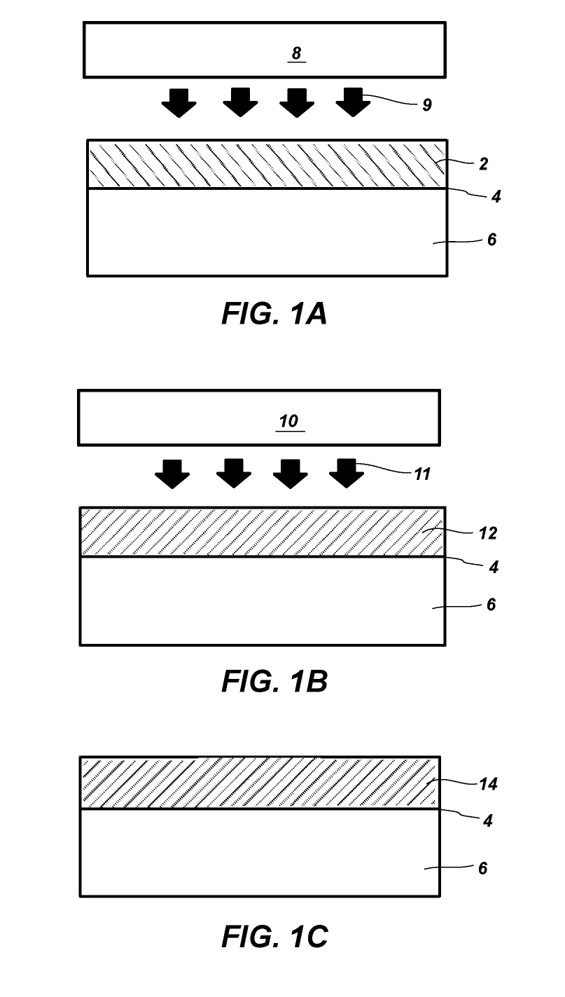

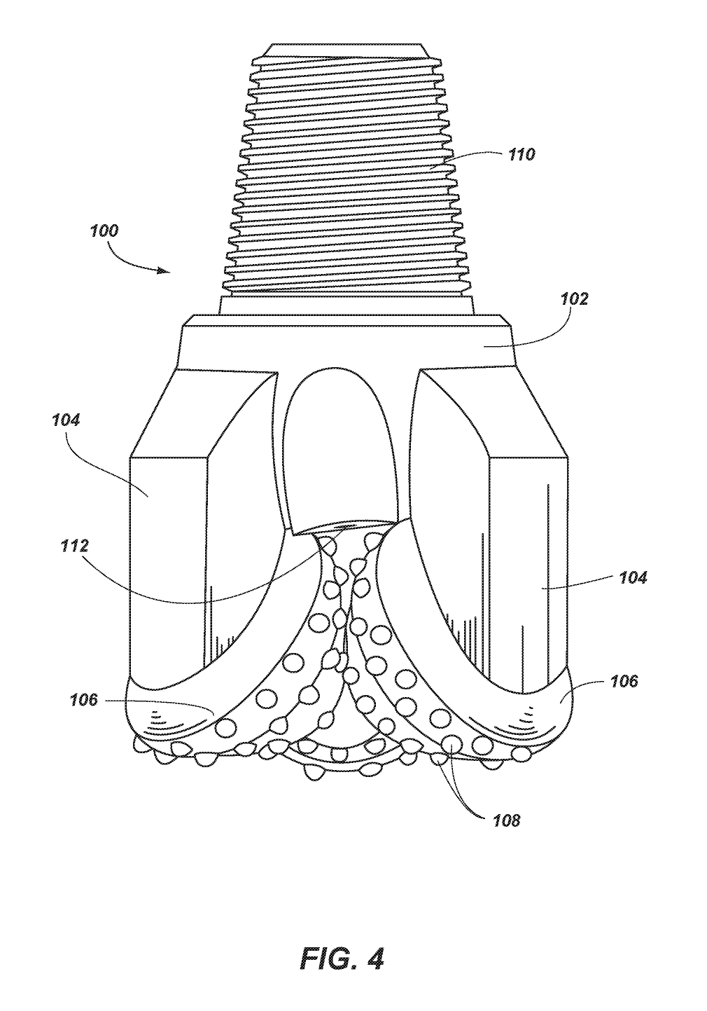

A volume of hard material comprising quenched carbon may be disposed on a component of a downhole tool according to embodiments of the present disclosure. In some embodiments, the volume of hard material of quenched carbon may be formed by methods disclosed, for example, in the Narayan references. FIGS. 1A-1E illustrate a method of forming a volume of hard material on a component of a downhole tool, such as downhole tools described herein with reference to FIGS. 4 through 14.

The volume of hard material may be formed by depositing an amorphous carbon film 2 on a surface 4 of a substrate 6, as illustrated in FIG. 1A. The amorphous carbon film 2 may be formed by a physical vapor deposition method, such as a pulsed laser deposition method. In the pulsed laser deposition method, the amorphous carbon film 2 may be deposited on a substrate by pulses of laser radiation, indicated by arrows 9, from a laser 8. The laser 8 may evaporate carbon material from a target and deposit the carbon material on the substrate 6 in a vacuum. In some embodiments, the laser 8 may be a KrF laser. In such embodiments, the KrF laser pulses may have a laser pulse duration of approximately 25 nanoseconds, a wavelength of approximately 248 nm, and an energy density of approximately 3.0 J/cm². The amorphous carbon film 2 may be formed to a thickness of between about 50 nm and about 2500 nm. The amorphous carbon film 2 may comprise a mixture of sp² bonded and sp³ bonded carbon. For example, the mixture may comprise between about 20% and 50% sp³ bonded carbon, with the remainder being sp² bonded carbon.

As illustrated in FIG. 1B, the amorphous carbon film 2 may be irradiated using pulses of laser radiation, indicated by arrows 11, using a laser 10. In some embodiments, the amorphous carbon film 2 may be irradiated in a controlled environment. For example, the amorphous carbon film 2 may be irradiated in an inert gas atmosphere. In other embodiments, the amorphous carbon film 2 may be irradiated in air. The amorphous carbon film 2 may further be irradiated in a vacuum or at ambient pressures.

The amorphous carbon film 2 may be irradiated with at least one laser pulse 11. The laser pulse 11 may be a nanopulse having a duration of less than 100 nanoseconds. In some embodiments, the laser 10 may be an ArF laser. In such embodiments, the amorphous carbon film 2 may be irradiated with at least one ArF laser pulse. The ArF laser pulse may have a pulse duration of about 20 nanoseconds, a wavelength of about 193 nm, and an energy density of between about 0.3 J/cm² and about 0.6 J/cm².

The laser 10 may be passed over a surface of the amorphous carbon film 2 to melt substantially the entire layer of amorphous carbon film 2. The laser pulse 11 may melt the amorphous carbon film 2 at temperatures between about 4000 K and 5000 K. The laser pulsing of the amorphous carbon as described herein may form liquid carbon 12 in an undercooled state, as illustrated in FIG. 1B. The undercooled state exists at approximately 4000 K or less and at ambient pressures.

The undercooled liquid carbon 12 may be rapidly quenched to form a quenched carbon layer 14 on the substrate 6, as illustrated in FIG. 1C. For example, the undercooled liquid carbon 12 may be quenched in air. The undercooled liquid carbon 12 may be quenched in still air, for example, by allowing the undercooled liquid carbon 12 to cool without air circulation at room temperatures. In other embodiments, the undercooled liquid carbon 12 may be quenched using an accelerated air quenching process by passing a stream of air over the undercooled liquid carbon 12. In yet other embodiments, the undercooled liquid carbon 12 may be quenched by other methods, such as water quenching, vacuum quenching, etc.

The quenched carbon layer 14 may be formed to a thickness of between about 20 nm and about 2000 nm and, more particularly, between about 1000 nm and 2000 nm. The quenched carbon layer 14 may have a hardness greater than diamond when measured using, for example, a wear (e.g., abrasion) test or a scratch hardness test. For example, the quenched carbon layer 14 may have a hardness of 35 GPa or greater when measured using a wear test according to ASTM G99, Standard Test Method for Wear Testing with a Pin-on-Disk Apparatus (2010). Further, a theoretical hardness of the quenched carbon layer 14 may be deduced from the carbon-to-carbon bond length or bond density, as described in J. Narayan et al., “Novel Phase of Carbon, Ferromagnetism, and Conversion into Diamond,” previously incorporated herein.

In some embodiments, the rate at which the undercooled liquid carbon 12 is quenched and the rate of nucleation and growth may be controlled to form nanodiamond, microdiamond, and thin films of single-crystal diamond in addition to, or instead of quenched carbon. In other words, the amorphous carbon film 2 may be directly converted into diamond at ambient pressures according to embodiments of the present disclosure. For example, the amorphous carbon film 2 may be directly converted into diamond at pressures less than 5 GPa. In some embodiments, the rate of quenching of the undercooled liquid carbon 12 after a first laser pulse 11 may be reduced to allow nucleation and growth of diamond grains within the undercooled liquid carbon 12. In such embodiments, the quenched carbon layer 14 may comprise diamond grains embedded in a matrix of quenched carbon. In other embodiments, the quenched carbon layer 14 may be irradiated with at least one additional laser pulse 11 and quenched to form diamond grains from quenched carbon in the quenched carbon layer 14. The diamond grains formed by the conversion of amorphous carbon and/or quenched carbon into diamond may have a grain size ranging from a few nanometers to about 800 nm. In yet other embodiments, the quenched carbon layer 14 may be irradiated with additional laser pulses 11 and quenched to form a thin film of single-crystal diamond.

In some embodiments, the substrate 6 may comprise a component of a downhole tool, such as components of any of the downhole tools illustrated in FIGS. 4 through 14. Thus, the quenched carbon layer 14 may be formed directly on a surface of the desired component of the downhole tool. In other words, the quenched carbon layer 14 may be formed in situ. In some embodiments, the desired component of the downhole tool may comprise a metallic material, and, thus, the substrate 6 may comprise a metal or metal alloy. In other embodiments, the quenched carbon layer 14 may be formed on a substrate 6 comprising a polymeric or ceramic material. For example, the quenched carbon layer 14 may be formed on a sapphire substrate, a glass substrate, or a high-density polyethylene (HDPE) substrate using methods as described in the Narayan references.

In other embodiments, the quenched carbon layer 14 may be formed on a surface of the desired component of the downhole tool in conjunction with an additive manufacturing process. Thus, the quenched carbon layer 14 may be formed directly on a surface of a partially formed component of a downhole tool that may not be accessible by line of sight laser pulses 9, 11 within the finished component of the downhole tool.

In yet other embodiments, the quenched carbon layer 14 may be formed elsewhere or remote from the component of the downhole tool and subsequently attached or deposited on the desired component of the downhole tool. In other words, the quenched carbon layer 14 may be formed ex situ. Thus, in some embodiments, the quenched carbon layer 14 may be separated from the substrate 6, as illustrated in FIG. 1D, and disposed on a second substrate 16, as illustrated in FIG. 1E. The second substrate 16 is a component of a downhole tool. The second substrate 16 may comprise a metallic material, a polymeric material, a ceramic material, or a combination thereof, such as a cermet material. The quenched carbon layer 14 may be attached to the second substrate 16 (e.g., the component of the downhole tool) by, for example, welding, brazing, soldering, molecular bonding, using adhesives, or mechanical locking by shrink fitting, pinning, splining, or keyways.

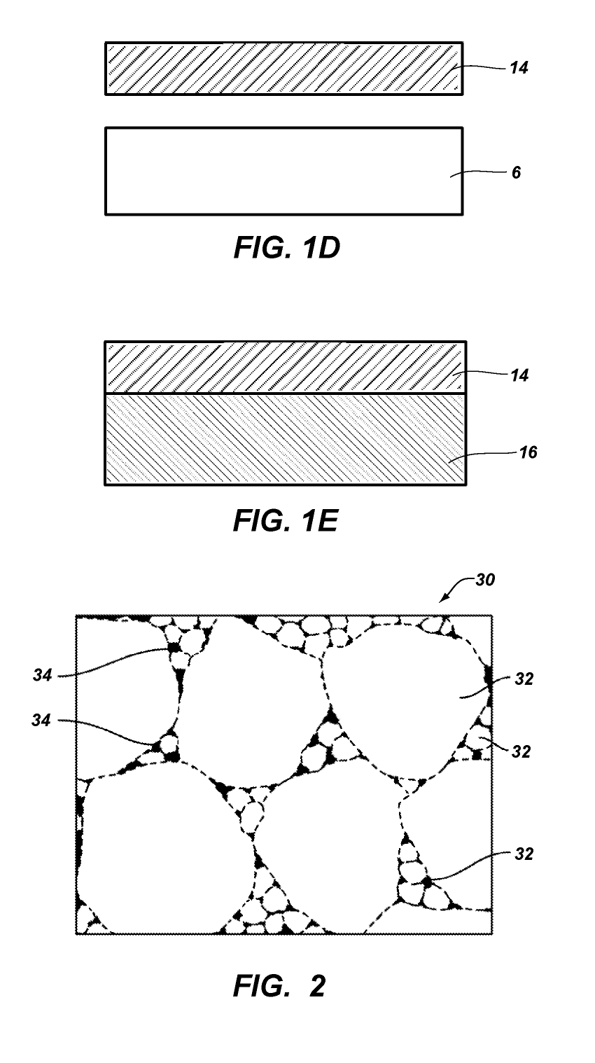

Embodiments of the present disclosure also relate to forming a polycrystalline compact comprising a plurality of particles or grains 32 of a hard material. FIG. 2 is an enlarged view illustrating how a microstructure of a polycrystalline compact 30 comprising grains 32 of hard material may appear under magnification. In some embodiments, the grains 32 may be interbonded. As used herein, the term “interbonded” means and includes any direct atomic bond (e.g., covalent, metallic, etc.) between atoms in adjacent grains. In some embodiments, the grains 32 may comprise grains of quenched carbon. In other embodiments, the grains 32 may comprise diamond grains formed by the conversion of amorphous carbon and/or quenched carbon into diamond as previously described herein with reference to FIGS. 1A-1C. In yet other embodiments, the grains 32 may comprise a combination of quenched carbon grains, synthetic diamond, natural diamond, and diamond grains formed by the conversion of amorphous carbon and/or quenched carbon into diamond as previously described. In additional embodiments, the grains 32 may comprise synthetic or natural diamond coated with quenched carbon. By way of non-limiting example, the grains 32 may be coated with quenched carbon by processes such as liquid sol-gel, flame spray pyrolysis, chemical vapor deposition (CVD), physical vapor deposition (PVD), atomic layer deposition (ALD), and other methods as described in, for example, U.S. Pat. No. 8,727,042, titled “Polycrystalline Compacts Having Material Disposed in Interstitial Spaces Therein, and Cutting Elements Including Such Compacts,” issued May 20, 2014, the entire disclosure of which is hereby incorporated herein by this reference.

The interstitial material 34 may comprise a metal or metal alloy. For example, the interstitial material 34 may comprise a catalyst material, such as a Group VIII metal-solvent catalyst including cobalt, iron, nickel, or alloys and mixtures thereof. The polycrystalline compact 30 may be formed by subjecting the grains 32 and the interstitial material 34 to a conventional high pressure, high temperature sintering process. For example, the HPHT sintering process may be as described, for example, in U.S. Pat. No. 8,858,662, titled “Methods of Forming Polycrystalline Tables and Polycrystalline Elements,” issued Oct. 14, 2014, the entire disclosure of which is hereby incorporated by this reference. In some embodiments, the interstitial material 34 may optionally be removed after HPHT sintering. For example, the interstitial material 34 may be removed by a leaching agent.

The polycrystalline compact 30 may be formed on or attached to the surface of the desired component of the downhole tool. In some embodiments, the polycrystalline compact 30 may be formed on a substrate, such as a cobalt-cemented tungsten carbide substrate to form a polycrystalline compact element including the polycrystalline compact 30 and the substrate, and the polycrystalline compact element may be attached to the surface of the desired component of the downhole tool.

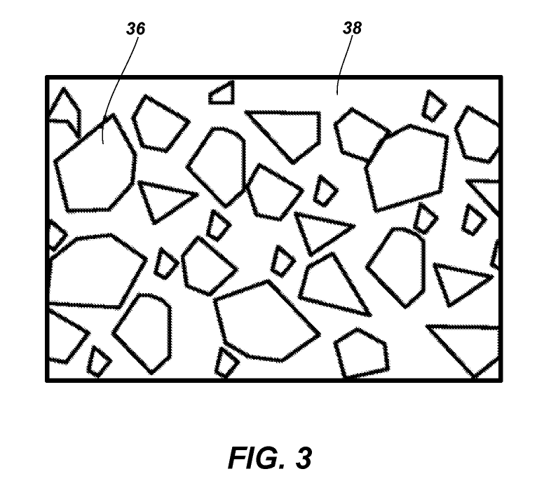

In yet other embodiments, a volume of hard material may comprise a plurality of particles or grains 36 of a hard material embedded in a matrix material 38, as illustrated in FIG. 3. In some embodiments, the grains 36 may comprise grains of quenched carbon. In other embodiments, the grains 36 may comprise diamond grains formed by the conversion of amorphous carbon and/or quenched carbon into diamond as previously described herein with reference to FIGS. 1A-1C. In yet other embodiments, the grains 36 may comprise grains of quenched carbon, diamond grains formed by the conversion of amorphous carbon and/or quenched carbon into diamond, synthetic diamond, natural diamond, or any combination thereof. In yet additional embodiments, the grains 36 may comprise grains of quenched carbon and grains of other hard materials including, for example, tungsten carbide and boron carbide. The matrix material 38 may comprise a bonding material including, for example, cobalt, tungsten, silicon, silicon carbide, etc. Materials comprising the diamond particles or grains 36 embedded in the matrix material 38 may be formed by a method as described, for example in U.S. Patent Publication No. 2011/0024198, titled “Bearing Systems Containing Diamond Enhanced Materials and Downhole Applications for Same,” filed on Oct. 11, 2010, the entire disclosure of which is hereby incorporated herein by this reference.

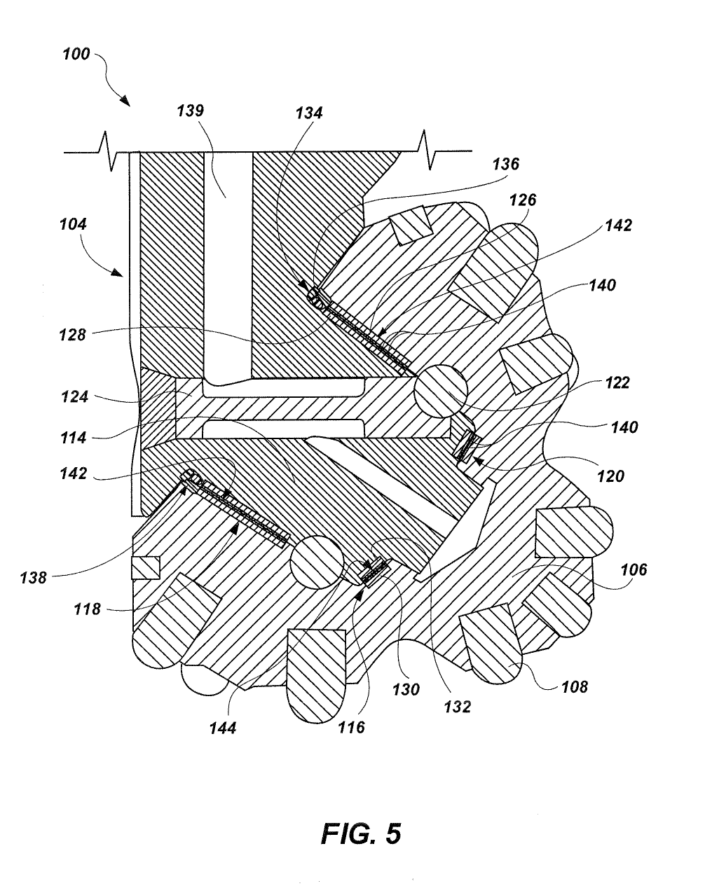

Embodiments of the present disclosure also relate to downhole tools comprising components with a wear-resistant volume of hard material comprising quenched carbon disposed thereon. FIG. 4 illustrates a roller cone drill bit 100, which is a downhole tool according to embodiments of the present disclosure. The drill bit 100 includes a bit body 102, such as a steel body, having three legs 104 depending therefrom. A roller cone 106 may be rotatably mounted to a bearing pin 114 (FIG. 5) on each of the legs 104. The roller cones 106 may have a plurality of cutting elements 108 mounted thereon. In some embodiments, each of the cutting elements 108 may comprise a polycrystalline compact 30 as previously described herein with reference to FIG. 2. In other embodiments, each of the cutting elements 108 may comprise a volume of hard material comprising the quenched carbon layer 14, as previously described herein with reference to FIGS. 1A-1E. In yet other embodiments, each of the cutting elements 108 may comprise a volume of hard material comprising a plurality of diamond grains 36 embedded in the matrix material 38, as described herein with reference to FIG. 3. The drill bit 100 includes a threaded portion 110 for connection to a drill string (not shown). The drill bit 100 may also include nozzles 112 through which drilling fluid may be discharged for cooling the cutting elements 108 and removing formation cuttings and returning the cuttings up to a surface of a formation during drilling operations.

FIG. 5 is a cross-sectional view of the roller cone drill bit 100 according to embodiments of the present disclosure. The roller cone 106 may be rotatably mounted to a bearing pin 114. At the interface between the roller cone 106 and bearing pin 114 is a bearing assembly 116. The bearing assembly 116 may include at least one radial bearing assembly 118 and at least one axial bearing assembly 120. The bearing assembly 116 may further include ball bearings 122 and a ball plug or retainer 124. The radial bearing assembly 118 may comprise a radial cone bearing member 126 and a radial journal bearing member 128, each of which may be configured to bear radial loads. The axial bearing assembly 120 may comprise an axial cone bearing member 130 and an axial journal bearing member 132, each of which may be configured to bear axial loads. The bearing assembly 116 may also include a seal assembly 134. The seal assembly 134 may comprise one or more of an elastomer seal, an elastomer seal component, and a metal face seal (MFS) 136. The MFS 136 may be disposed in a seal cavity 138 between the bearing pin 114 and the roller cone 106, and may seal lubricant and other fluids within a channel 139, which may be formed in the roller cone 106.

A volume of hard material 140 may be disposed on at least one component of the bearing assembly 116. In some embodiments, the volume of hard material 140 may be applied to a surface of bearing assembly 116 components susceptible to wear or erosion caused by contact between or rubbing against other components of the bearing assembly 116. For example, the volume of hard material 140 may be disposed on at least one surface of the radial bearing assembly 118 and the axial bearing assembly 120, including at least one of the radial cone bearing member 126, the radial journal bearing member 128, the axial cone bearing member 130, and the axial journal bearing member 132. In particular, the volume of hard material 140 may be provided at a first interface 142 at which the radial cone bearing member 126 and the radial journal bearing member 128 abut against one another and are configured to rotationally slide against one another. The volume of hard material 140 may also be provided at a second interface 144 at which the axial cone bearing member 130 and the axial journal bearing member 132 abut against one another and are configured to rotationally slide against one another. In other embodiments, the volume of hard material 140 may further be disposed on a surface of bearing assembly 116 components susceptible to wear or erosion caused by the flow of fluids in the bearing assembly 116. For example, the volume of hard material 140 may be disposed on components of the sealing assembly 134, such as the MFS 136.

In some embodiments, the volume of hard material 140 may comprise a quenched carbon layer 14, as described herein with reference to FIGS. 1A-1E. In other embodiments, the volume of hard material 140 may comprise a polycrystalline compact such as the polycrystalline compact 30 comprising diamond grains 32 formed from quenched carbon, as described herein with reference to FIG. 2. In yet other embodiments, the volume of hard material 140 may comprise a plurality of diamond grains 36 embedded in the matrix material 38, as described herein with reference to FIG. 3.

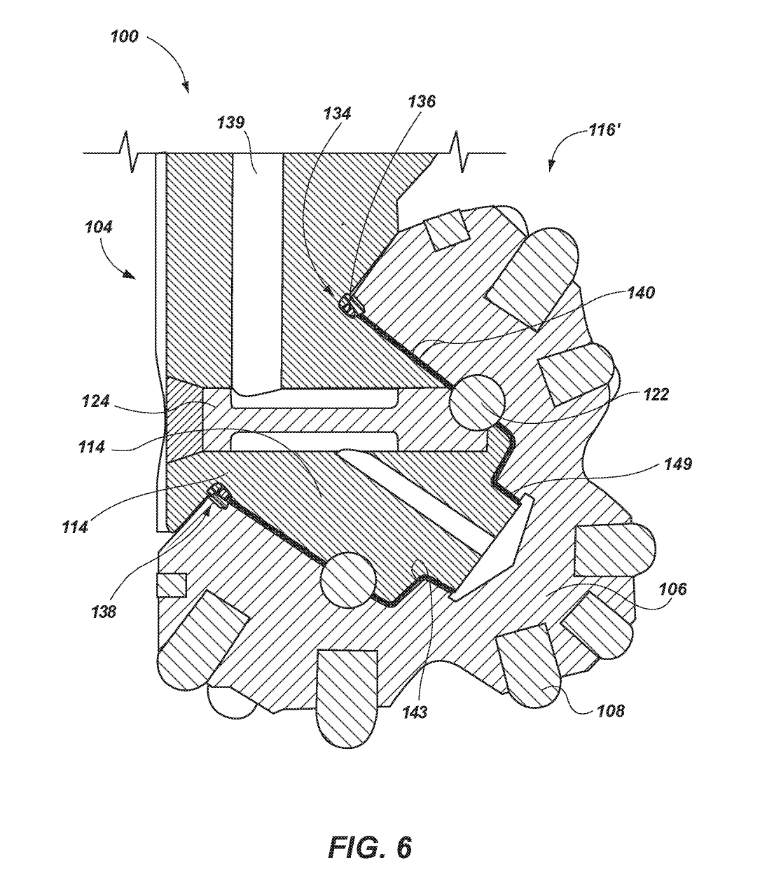

In other embodiments, the volume of hard material 140 may be applied directly to interior surfaces 143 of the roller cone 106 and/or the exterior surfaces 149 of the bearing pin 114, as illustrated in FIG. 6. For example, the bearing assembly 116′ illustrated in FIG. 6 may lack a radial bearing assembly, such as the radial bearing assembly 118, and/or an axial bearing assembly, such as the axial bearing assembly 120, as previously described herein with reference to FIG. 5. The volume of hard material 140 may be applied to surfaces of the bearing assembly 116′ components susceptible to wear or erosion caused by contact between or rubbing against other components of the bearing assembly 116′.

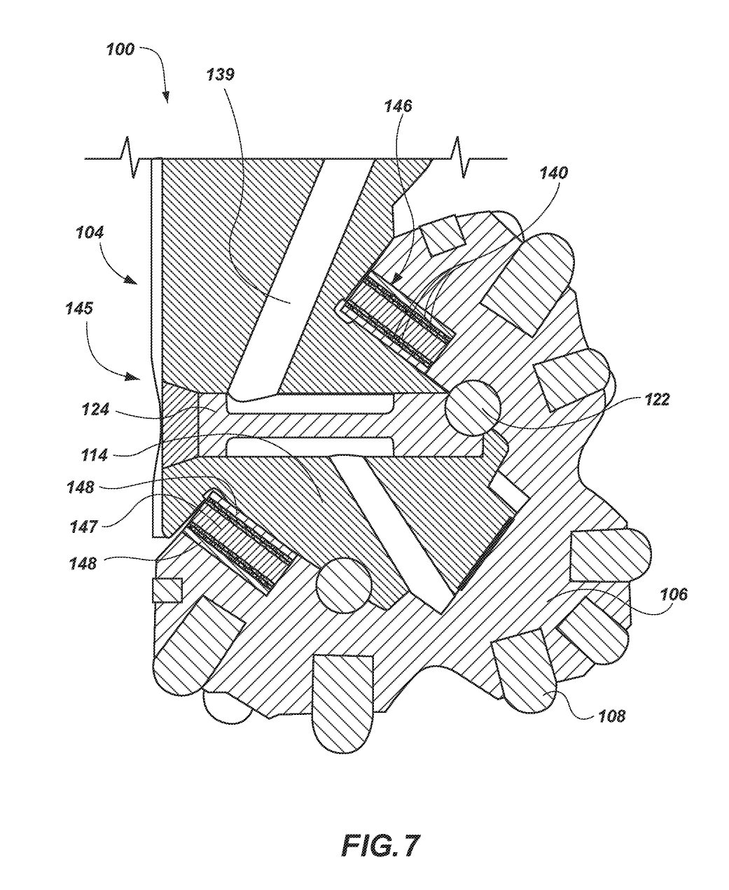

In yet other embodiments, the bearing assembly may lack a sealing assembly, such as the seal assembly 134 of FIGS. 5 and 6. For example, the bearing assembly may be an open bearing assembly 145 as illustrated in FIG. 7. Thus, fluid, such as drilling fluid or air, may be provided through the channel 139 and directed through the open bearing assembly 145 during the operation thereof. The open bearing assembly 145 may include a roller bearing assembly 146. The roller bearing assembly 146 may include a roller 147 and a bearing race 148.

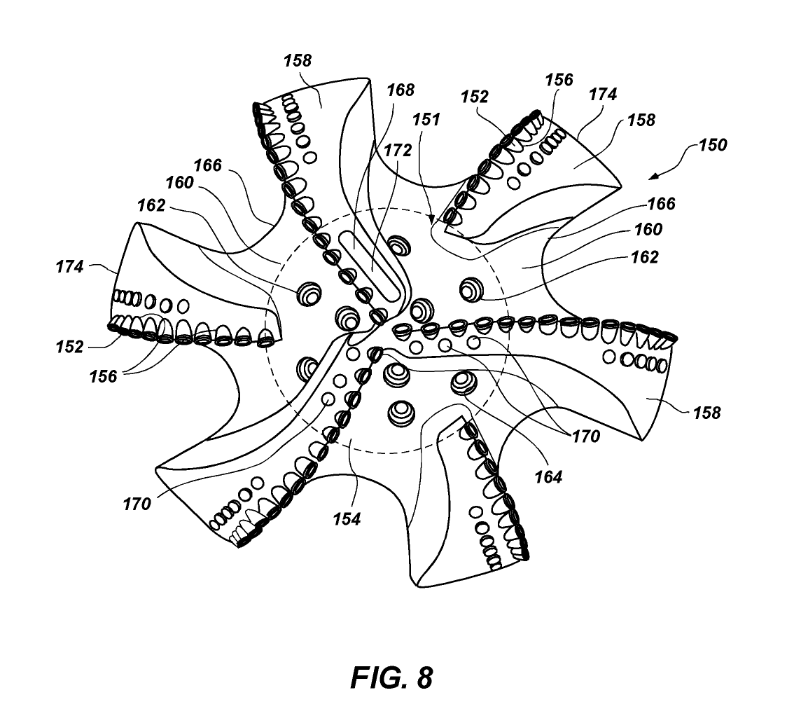

The volume of hard material 140 may be applied to a surface of open bearing assembly 145 components susceptible to wear or erosion caused by contact between or rubbing against other components of the open bearing assembly 145. For example, the volume of hard material 140 may be disposed on at least one of the roller 147 and the bearing race 148. FIG. 8 illustrates a face or leading end 151 of drill bit 150 according to embodiments of the present disclosure. The drill bit 150 is a fixed cutter or drag bit, and is a downhole tool that, like the drill bit 100, may comprise at least one component having the volume of hard material 140 disposed thereon. The drill bit 150 includes a plurality of cutting elements 152 mounted on a tool body 154, such as a steel body. Each of the cutting elements 152 may comprise a polycrystalline compact 30 as previously described herein with reference to FIG. 2. In other embodiments, each of the cutting elements 152 may comprise a volume of hard material comprising quenched carbon layer 14 as previously described herein with reference to FIGS. 1A-1E. In yet other embodiments, each of the cutting elements 152 may comprise a volume of hard material comprising plurality of diamond grains 36 embedded in the matrix material 38, as described herein with reference to FIG. 3. In some embodiments, the cutting elements 152 may be disposed in pockets 156 forming in a surface of the blades 158. The cutting elements 152 may be coupled to the blades 158 and within the pockets 156 thereof by welding, brazing, and adhering using a high-strength adhesive. Fluid courses 160 may lie between the blades 158 and may be provided with drilling fluid by nozzles 162 secured in nozzle orifices 164. Fluid courses 160 extend to junk slots 166 extending upwardly along the side of the bit 150 between blades 158. Gage pads (not shown) may comprise longitudinally upward extensions of blades 158 and may have wear-resistant inserts or coatings on radially outer surfaces 174 thereof. Formation cuttings may be swept away from the cutting elements 152 by drilling fluid emanating from nozzle orifices 164 that flows generally radially outwardly through fluid courses 160 and then upwardly through junk slots 166 to an annulus between a drill string from which the bit 150 may be attached and on to a surface of a subterranean formation.

The drill bit 150 may also depth-of-cut control (DOCC) features, such as bearing blocks 168, and wear-resistant elements or inserts 170. The bearing blocks 168 may rotationally trail the cutting elements 152. The bearing blocks 168 may include a bearing or rubbing area 172 affording a surface area tailored to provide support for the bit 150 under axial or longitudinal weight-on-bit (WOB) on a selected formation being drilled without exceeding the compressive strength thereof. The bearing blocks 168 may further provide a desired depth-of-cut (DOC). In some embodiments, the bearing blocks 168 may be as described in, for example, U.S. Patent Publication No. 2010/0276200, titled “Bearing Blocks for Drill Bits, Drill Bit Assemblies Including Bearing Blocks and Related Methods,” filed on Apr. 26, 2010, the entire disclosure of which is hereby incorporated by this reference. The wear-resistant inserts 170 may be provided to reduce the abrasive wear encountered by contact with the formation being drilled, which is further influenced by WOB as the drill bit 150 rotates under applied torque. The drill bit 150 may further comprise additional DOCC features and wear-resistant inserts in lieu of or in addition to the bearing blocks 168 and the wear-resistant inserts 170. For instance, the drill bit 150 may include gage pads, wear pads, wear knots, ovoids, or other blunt features as described in, for example, U.S. Pat. No. 6,298,930, titled “Drill Bits with Controlled Cutting Loading and Depth of Cut,” issued on Oct. 9, 2001; U.S. Pat. No. 6,460,631, titled “Drill Bits with Reduced Exposure of Cutters,” issued Oct. 8, 2002; U.S. Patent Publication No. 2013/0081880, “Drill Bit Design for Mitigation of Stick Slip,” filed on Sep. 28, 2012; and U.S. Pat. No. 6,779,613, titled “Drill Bits with Controlled Exposure of Cutters,” issued Aug. 24, 2004, the entire disclosure of each of which is hereby incorporated by this reference.

The volume of hard material 140 may be disposed on at least one component of the drill bit 150. In some embodiments, the volume of hard material 140 may be disposed on a surface of drill bit 150 components subject to wear by contact with a subterranean formation during drilling operations and/or susceptible to wear or erosion caused by the flow of fluid (e.g., drilling fluid) through or adjacent the component. For example, the volume of hard material 140 may be disposed on at least one of the bearing or rubbing area 172 of the bearing block 168, on the wear-resistant elements 170, or gage pads on radially outer surfaces 174 of the blades 158. In other embodiments, the volume of hard material 140 may be provided on any DOCC feature or wear-resistant insert that may be provided on the drill bit 150. In other embodiments, the volume of hard material 140 may also be disposed on surfaces of drill bit 150 components susceptible to wear or erosion caused by the flow of fluids. For example, the volume of hard material 140 may be disposed on surfaces of the nozzles 162 exposed to fluid flow and on surfaces of the tool body 154 within the fluid courses 160 and junk slots 166.

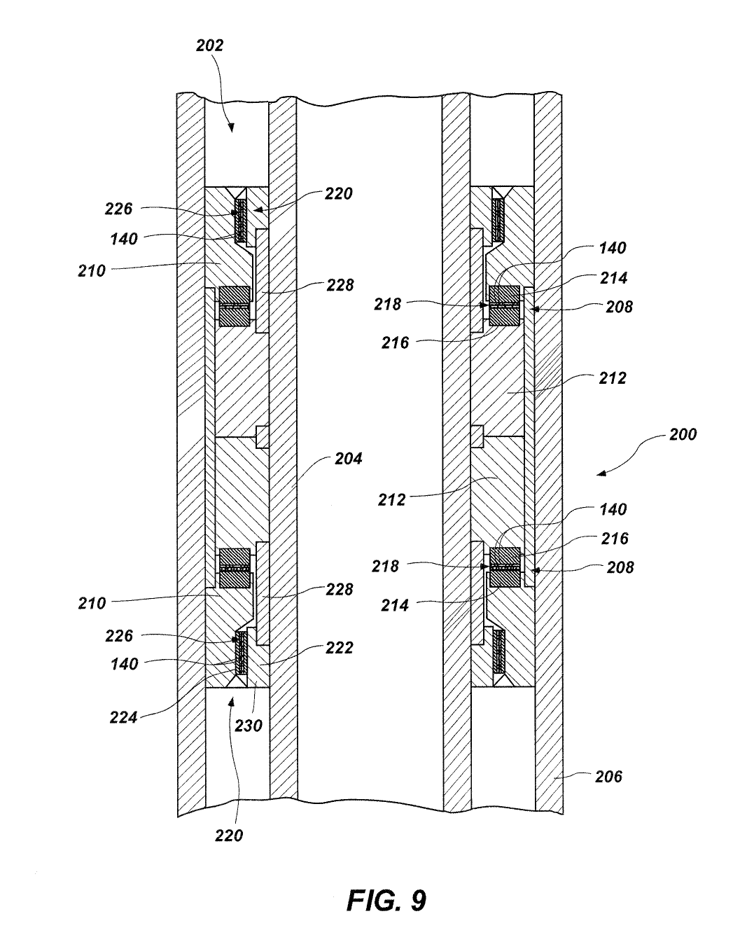

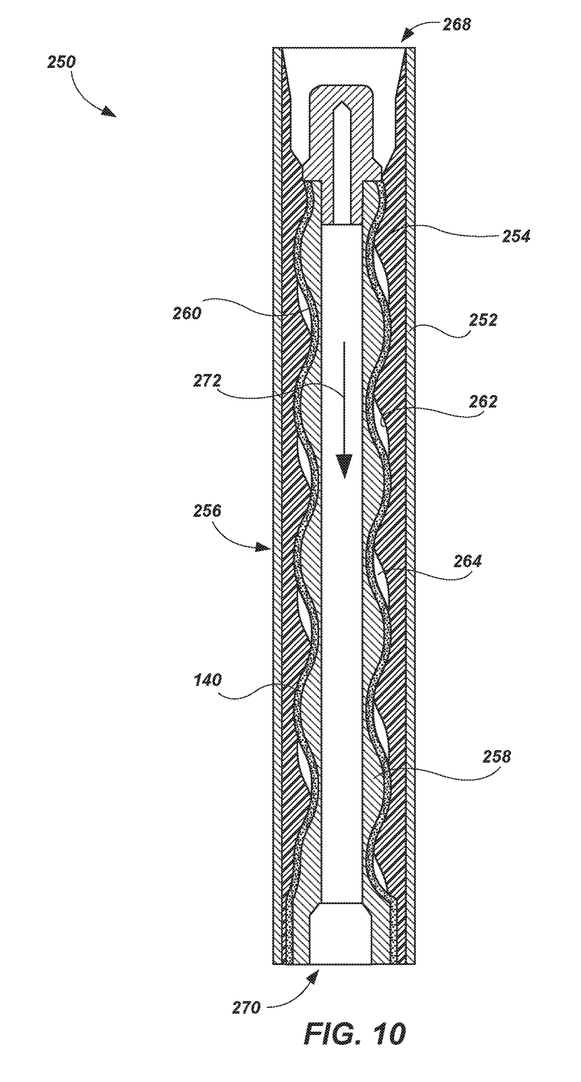

FIG. 9 illustrates a downhole motor 200, which is a downhole tool, including at least one component having the volume of hard material 140 according to embodiments of the present disclosure disposed thereon. The downhole motor 200 includes at least one bearing assembly 202. The bearing assembly 202 may be used in downhole tools including, but not limited to, pumps, motors, turbines, and rotary steerable tools. The downhole motor 200 includes a central tubular downhole motor driveshaft 204 located rotatably within a tubular bearing housing 206, with the bearing assembly 202 of downhole motor 200 located and providing for relative rotation between the driveshaft 204 and the housing 206. The driveshaft 204 may be rotated by the action of the power section 250 (FIG. 10) of the downhole motor 200 and may supply rotary drive to a drill bit, such as the roller cone drill bit 100 of FIG. 4 or the fixed cutter drill bit 150 of FIG. 8. The housing 206 may remain rotationally stationary during motor operation.

The bearing assembly 202 may include at least one annular axial bearing assembly 208. As illustrated in FIG. 9, the bearing assembly 202 includes two annular axial bearing assemblies 208. Each axial bearing assembly 208 may include an outer bearing ring 210 and an inner bearing ring 212. The outer bearing ring 210 may include a first axial bearing member 214, and the inner bearing ring 212 may include a second axial bearing member 216. The first axial bearing member 214 abuts against the second axial bearing member 216 at an interface 218. The first and second axial bearing members 214, 216 are configured to rotationally slide against one another and to bear axial loads acting on the downhole motor 200.

The bearing assembly 202 may also include at least one annular radial bearing assembly 220. As illustrated in FIG. 9, the bearing assembly 202 includes two annular radial assemblies 220. Each radial bearing assembly 220 may include a first rotating radial bearing member 222 and a second rotating radial bearing member 224. The outer bearing ring 210 may further include the second radial bearing member 224. A radial bearing ring 230 may include the first rotating radial bearing member 222. The first radial bearing member 222 abuts against the second radial bearing member 224 at a bearing interface 226. The first and second radial bearing members 222, 224 are configured to rotationally slide against one another and to bear radial loads acting on the downhole motor 200. The first radial bearing member 222 may be concentrically nested with the outer bearing ring 210, and a spacer ring 228 may be concentrically nested with the radial bearing member 222.

The volume of hard material 140 may be disposed on at least one component of the bearing assembly 202 of the downhole motor 200. In some embodiments, the volume of hard material 140 may be disposed on surfaces of bearing assembly 202 components susceptible to wear or erosion caused by contact between or rubbing against other components of the bearing assembly 202. For example, the volume of hard material 140 may be disposed on at least one of the first and second axial bearing members 214, 216 of the axial bearing assembly 208 at the interface 218. The volume of hard material 140 may further be disposed on at least one of the first and radial bearing members 222, 224 of the radial bearing assembly 220 at the bearing interface 226.

A power section, such as the power section 250 illustrated in FIG. 10, of the downhole motor 200 may be positioned above the bearing assembly 202 (FIG. 9). The power section 250 may include an elongated metal housing 252, which may be coupled to the housing 206 (FIG. 9) of the bearing assembly 202. The housing 252 may have an interior lined with an elastomeric member 254. The elastomeric member 254 may be secured inside the metal housing 252 by bonding an elastomeric material within the interior of the metal housing 252. The elastomeric member 254 and the metal housing 252 may together form a stator 256 of the power section 250. A rotor 258 may be rotatably disposed within the stator 256.

The rotor 258 may have a helically contoured or lobed outer surface 260 configured to engage with a helically contoured or lobed inner surface 262 of the stator 256. The outer surface 260 and the inner surface 262 may have similar, but slightly different profiles. For example, the outer surface 260 may have one fewer lobe than the inner surface 262. The outer surface 260 of the rotor 258 and the inner surface 262 of the stator 256 are configured so that seals are established directly between the rotor 258 and the stator 256 at discrete intervals along and circumferentially around the interface therebetween, resulting in the creation of fluid chambers or cavities 264 between the outer surface 260 of the rotor 258 and the inner surface 262 of the stator 256. The cavities 264 may be filled by a pressurized drilling fluid.

As the pressurized drilling fluid flows from a top 268 to a bottom 270 of the power section 250, in the direction shown by arrow 272, the pressurized drilling fluid causes the rotor 258 to rotate in a planetary-type motion within the stator 256. The number of lobes and the geometries of the outer surface 260 of the rotor 258 and inner surface 262 of the stator 256 may be modified to achieve desired input and output requirements and to accommodate different drilling operations. The rotor 258 may be coupled to a flexible shaft (not shown), and the flexible shaft may be connected to the driveshaft 204 in the bearing assembly 202 (FIG. 9). As previously mentioned, a drill bit may be attached to the driveshaft 204. For example, the driveshaft 204 may include a threaded box, and a drill bit may be provided with a threaded pin (e.g., threaded portion 110 of FIG. 4) that may be engaged with the threaded box of the drive shaft 204.

While the stator 256 may comprise an elastomeric member 254 that is at least substantially comprised of an elastomeric material, in other embodiments, the stator 256 may be formed of a metallic material, such as steel. Such metallic stators 256 are described in, for example, U.S. Pat. No. 6,543,132, titled “Methods of Making Mud Motors,” issued Apr. 8, 2003, the entire disclosure of which is incorporated herein by this reference.

The volume of hard material 140 may be applied to at least one internal surface of components of the power section 250. In some embodiments, the volume of hard material 140 may be disposed on power section 250 components susceptible to wear or erosion caused by contact between or rubbing against other components of the power section 250. In other embodiments, the volume of hard material 140 may further be disposed on power section 250 components susceptible to wear or erosion caused by the flow of fluids in the power section 250. For example, the volume of hard material 140 may be applied to at least one of the outer surface 260 of the rotor 258 or the inner surface 262 of the stator 256.

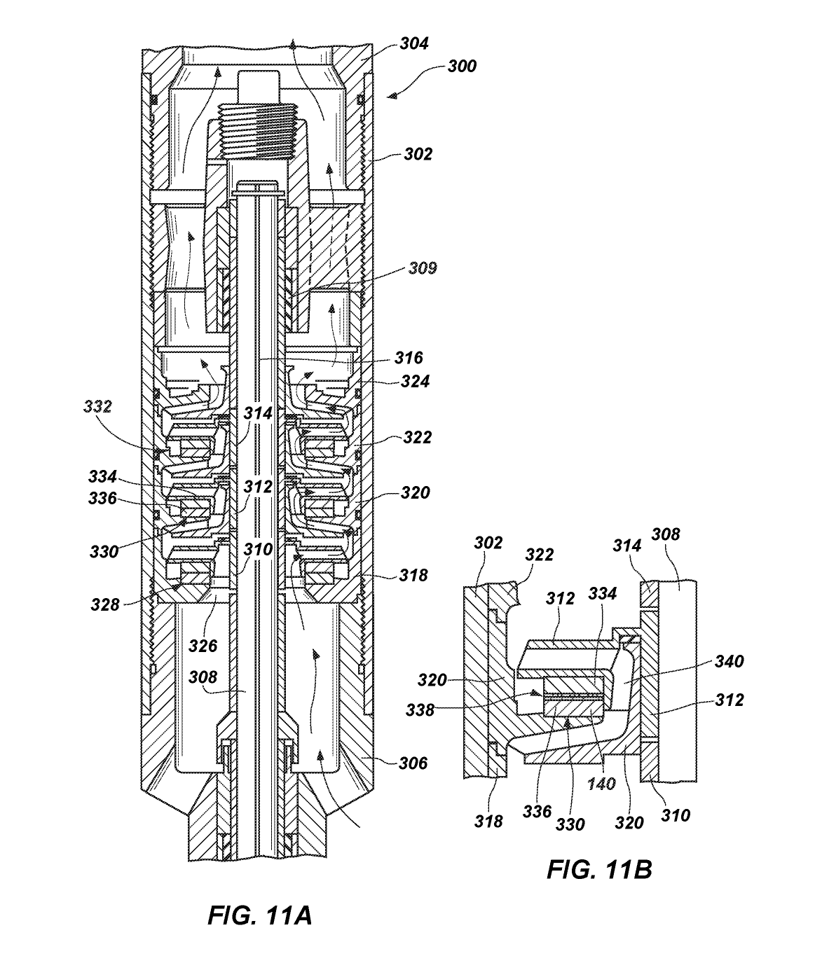

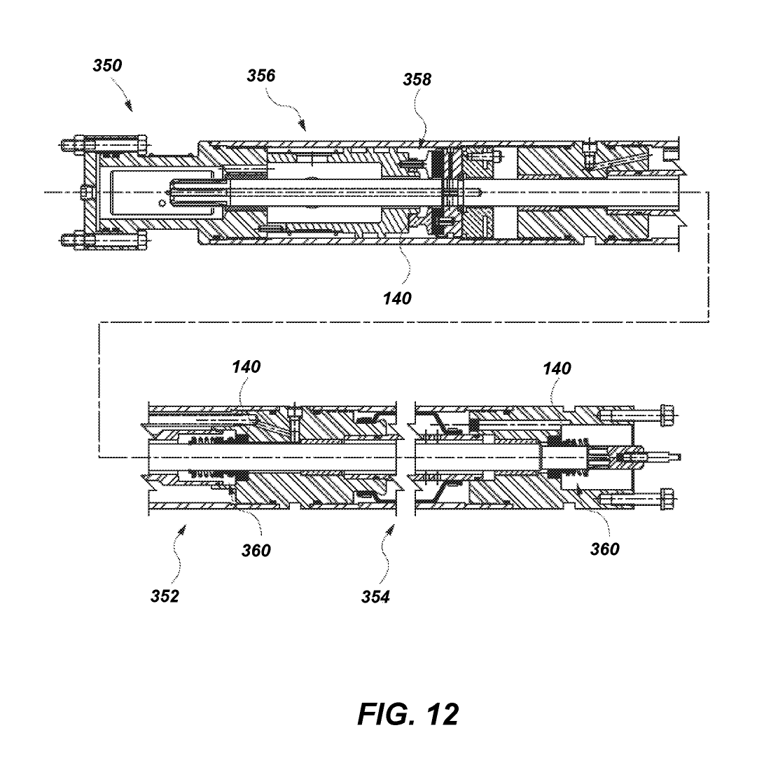

FIGS. 11A, 11B, and 12 illustrate a cross-sectional view of a portion of an electric submersible pump (ESP), which is a downhole tool having at least one component with a volume of hard material according to embodiments of the present disclosure disposed thereon. The ESP may include a pump assembly 300, as illustrated in FIGS. 11A and 11B, and a seal assembly 350, as illustrated in FIG. 12.

The pump assembly 300 may include an outer housing 302 that may be provided at its upper end with a first adaptor 304. The lower end of the housing 302 may be provided with a second adaptor 306 that may connect the housing 302 to a seal assembly 350, as illustrated in FIG. 12. The seal assembly 350 may be connected at its lower end to a submersible electric motor (not shown) for driving the pump assembly 300. A pump shaft 308, which is rotated by the motor, extends upwardly into the pump assembly 300.

The pump shaft 308 may be rotatably coupled to the housing 302 and may be maintained in a radial position relative to the housing 302 by at least one radial bearing 309. The pump shaft 308 may also be connected for rotation with impellers 310, 312, 314 by means of a key 316. The pump assembly 300 also includes diffusers 318, 320, 322, and 324. The diffusers 318, 320, 322, 324 include a centrally located annular opening 326 providing for a flow of fluid into the impeller 310, 312, 314. The diffusers 318, 320, 322, 324 may be fixably coupled to the housing 302 and may be positioned relative to impellers 310, 312, 314 such that the impellers 310, 312, 314 and the diffusers 318, 320, 322, 324 define a fluid path 340 therebetween. To provide for the smooth rotation of the impellers 310, 312, 314 relative to the diffusers 318, 320, and 322, bearing assemblies 328, 330, 332 for carrying both thrust and radial loads are located between a respective impeller and diffuser.

FIG. 11B is an enlarged view of the bearing assembly 330 of FIG. 11A. As shown in FIG. 11B, the bearing assembly 330 may include a first bearing member 334 and a second bearing member 336. The first bearing member 334 may be bonded to the impeller 312 and the second bearing member 336 may be bonded to the diffuser 320.

In operation of the pump assembly 300, the motor causes the pump shaft 308 to rotate which causes the impellers 310, 312, 314 to rotate and which causes fluid to pass through the pump assembly 300 along the flow path 340 as illustrated by the arrows in FIG. 11A. As the impellers 310, 312, 314 rotate relative to the respective diffusers 318, 320, 322, and 324, the first bearing member 334 and the second bearing member 336 of each of the bearing assemblies 328, 330, 332 run against one another at a bearing interface 338.

The volume of hard material 140 may be disposed on at least one component of the pump assembly 300. In some embodiments, the volume of hard material 140 may be applied to a surface of the pump assembly 300 components susceptible to wear or erosion caused by contact between or rubbing against other components of the pump assembly 300. For example, the volume of hard material 140 may be disposed on at least one of the members of the bearing assemblies 328, 330, 332, such as the first bearing member 334 and the second bearing member 336 of the bearing assembly 330, at an interface, such as the bearing interface 338, therebetween, and may be disposed on the radial bearing 309 adjacent the pump shaft 308. In other embodiments, the volume of hard material 140 may further be disposed on surfaces of pump assembly 300 components susceptible to wear or erosion caused by the flow of fluids in the pump assembly 300. For example, the volume of hard material 140 may further be disposed on at least one of the impellers 310, 312, 314, or the diffusers 318, 320, 322, and 324.

The seal assembly 350 of FIG. 12 may prevent well fluids from entering the motor (not shown) of the ESP and allow pressure to equalize between the motor oil and well fluids. In some embodiments, the seal assembly 350 may be positioned between the motor and the pumping assembly 300, providing an area for expansion of the motor oil, equalizing pressure between the well fluid and the motor, isolating the motor oil from the well fluid to prevent contamination, and supporting the thrust load of the pump shaft 308.

The seal assembly 350 may include at least one labyrinth chamber 352 and elastomer bag seals 354. Each labyrinth chamber 352 may include an oil path that reverses its vertical direction twice. Due to the density differences between the motor oil and the well fluid, this arrangement may facilitate the maintenance of the motor oil at the top of the labyrinth chamber 352 and denser well fluids at the bottom of the labyrinth chamber 352. Each elastomer bag seal 354 provides a physical barrier between the motor oil and the well fluid to provide separation of the motor oil and well fluid. In view of this, the elastomer bag seals 354 may maintain the separation of motor oil and well fluid having substantially the same density. However, if the elastomer bag ruptures, the seal may fail. The seal assembly 350 may additionally include a heat exchanger 356, one or more bearing members, such as thrust bearings 358, and mechanical seals 360.

The volume of hard material 140 may be disposed on at least one component of the seal assembly 350. In some embodiments, the volume of hard material 140 may be disposed on a surface of the seal assembly 350 components susceptible to wear or erosion by contact between or rubbing against other components of the seal assembly 350. In other embodiments, the volume of hard material 140 may further be disposed on a surface of components susceptible to wear or erosion caused by the flow of fluids in the seal assembly 350. For example, the volume of hard material 140 may be disposed on at least one of the bearing members 358 or mechanical seals 360.

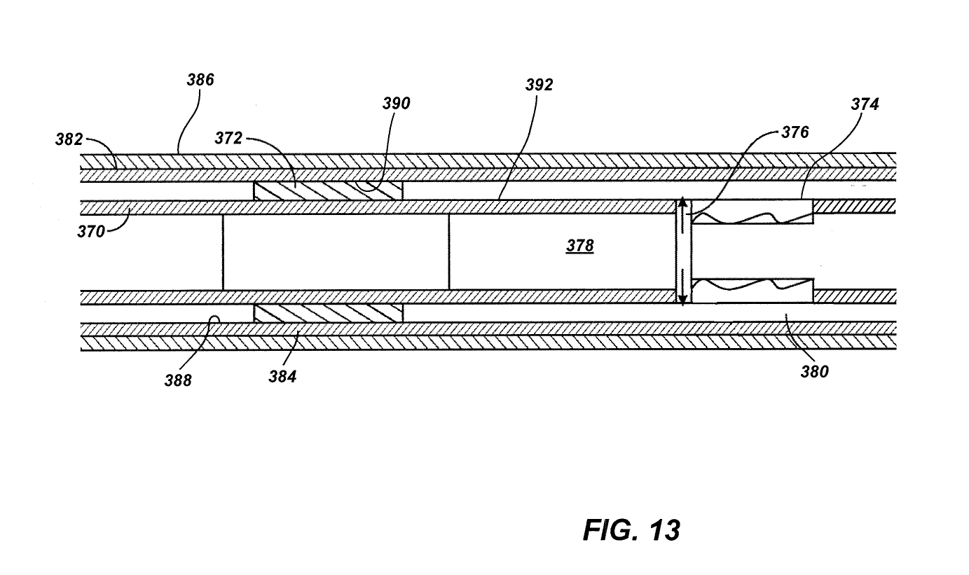

FIG. 13 illustrates a portion of a drill string 370, which is a downhole tool having a volume of hard material according to an embodiment of the present disclosure disposed thereon. The drill string 370 may include stabilizers 372 for supporting the drill string 370, a power device 374, and bypass ports 376 for injecting drilling fluid from bore 378 to an annulus 380, which may be defined between the drill string 370 and a wellbore wall 382 within a subterranean formation. In some embodiments, the wellbore 386 may be lined with a metal casing 384. The power device 374 may comprise a motor or turbine for rotating one or more portions of the drill string 370 and/or any other devices that supply energy to one or more downhole tools.

The stabilizers 372 may be positioned on the string 370 to provide stability and strength and to minimize the effects of whirl, bit bounce, axial and lateral vibrations, buckling, and other drilling dysfunctions. The stabilizers 372 may comprise wear pads that provide a contact wear surface against the wellbore wall 382 or metal casing 384, when present. In some embodiments, the stabilizers 370 may be attached to and rotate with the string 370. In other embodiments, the stabilizers 372 may include bearing assemblies that permit the stabilizer 372 to be relatively non-rotating relative to the wellbore 386. The stabilizer 372 may be formed and configured as described, for example, in U.S. Pat. No. 9,062,503, titled “Rotary Coil Tubing Drilling and Completion Technology,” issued Jun. 23, 2015; and U.S. Pat. No. 6,907,944, titled “Apparatus and Method for Minimizing Wear and Wear Related Measurement Error in a Logging-While-Drilling Tool,” issued Jun. 21, 2005, the entire disclosure of each of which is hereby incorporated by this reference.

The volume of hard material 140 may be disposed on at least one component of the drill string 370. In some embodiments, the volume of hard material 140 may be disposed on a surface of drill string 370 components susceptible to wear or erosion caused by contact with a subterranean formation during drilling operations. In other embodiments, the volume of hard material 140 may further be disposed on a surface of drill string 370 components susceptible to wear or erosion caused by the flow of fluids in or about the drill string 370. For example, the volume of hard material 140 may be disposed on an outer surface 390 of the stabilizers 372, such as on wear pads disposed on the stabilizers 372, on an outer surface 392 of the drill string 370, or an inner surface 388 of the metal casing 384.

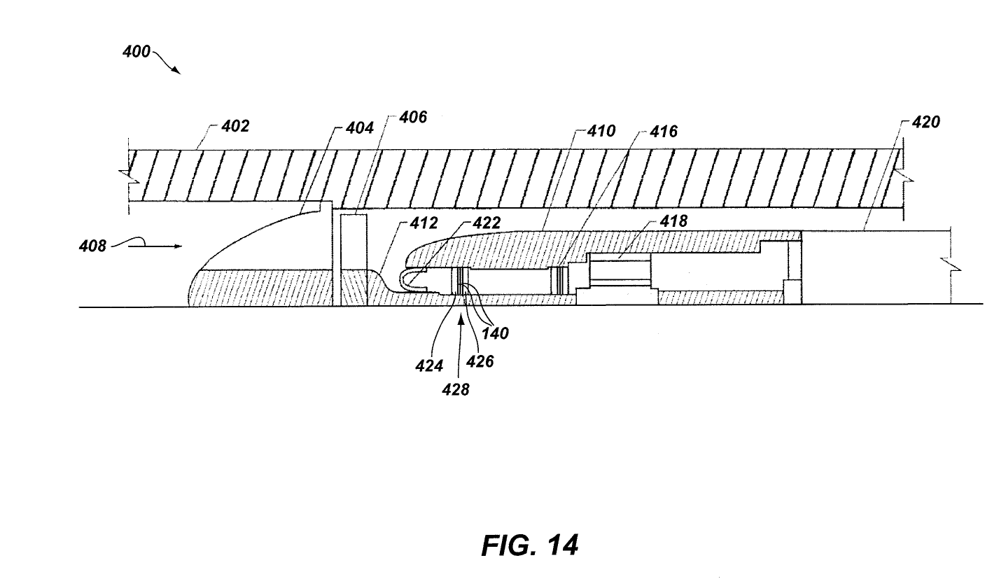

FIG. 14 illustrates a mud pulser 400 of a bidirectional communication and power module (BCPM) for mud pulse telemetry. The mud pulser 400 may induce pressure fluctuations in the drilling fluid. The pressure fluctuations, or pulse, propagate to the surface through a drill string and are detected at the surface by a sensor and a control unit. The BCPM provides power to equipment of a bottom-hole assembly (BHA), such as a steering unit, and provides two-way data communication between the BHA and surface devices. The pulser 400 is located in an inner bore of a tool housing 402. The pulser 400 includes a stator 404 and a rotor 406. Drilling fluid (e.g., drilling mud) may flow through the stator 404 and the rotor 406 in the direction indicated by the directional arrow 408 and pass through an annulus between the pulser housing 410 and the tool housing 402. The rotor 406 may be attached to a shaft 412. The shaft 412 passes through a flexible bellows and fits through bearing assemblies 416, which fix the shaft 412 in radial and axial locations with respect to the pulser housing 410. The shaft 412 may be connected to an electric motor 418. The motor 418 may be electronically controlled, by circuitry in the electronics module 420, to allow the rotor 406 to be driven. In some embodiments, lubricant may be provided within the pulser housing 410 to lubricate the bearing assemblies 416. The bearing assembly 416 may comprise a first bearing member 424 and a second bearing member 426. A seal 422 may be coupled to the shaft 412 and the pulser housing 410 and hermetically seal the lubricant within the pulser housing 410.

The volume of hard material 140 may be disposed on at least one component of the mud pulser 400. In some embodiments, the volume of hard material 140 may be disposed on surfaces of the mud pulser 400 components that are susceptible to wear or erosion caused by the flow of drilling fluid or other fluids, such as lubricant, therethrough. For example, the volume of hard material 140 may be disposed on the stator 404, the rotor 406, the pulser housing 410, the tool housing 402, the motor 418, and the seal 422. In other embodiments, the volume of hard material 140 may be disposed on a surface of the mud pulser 400 components susceptible to or erosion caused by contact between or rubbing against other components of the mud pulser 400. For example, the volume of hard material 140 may be disposed on the between the first and second bearing members 424, 426 at an interface 428 at which the bearing members 424, 426 abut against and rotationally slide against one another.

Additional non-limiting example embodiments of the present disclosure are set forth below.

Embodiment 1: A method of forming a volume of hard material on a component of a downhole tool, comprising: depositing a film of amorphous carbon on a substrate, wherein the substrate comprises a component of a downhole tool, irradiating the film of amorphous carbon to form a liquid carbon in an undercooled state, and quenching the liquid carbon to form a layer of quenched carbon on the substrate.

Embodiment 2: The method of Embodiment 1, wherein depositing the film of amorphous carbon on the substrate comprises depositing the film of amorphous carbon on the substrate using a pulsed laser deposition method.

Embodiment 3: The method of Embodiments 1 or 2, wherein irradiating the film of amorphous carbon comprises irradiating the film of amorphous carbon using a laser.

Embodiment 4: The method of Embodiment 3, wherein irradiating the film of amorphous carbon to form liquid carbon comprises melting the film of amorphous carbon at a temperature of between about 4000 K and about 5000 K.

Embodiment 5: The method of any of Embodiments 1 through 4, further comprising forming the layer of quenched carbon to a thickness of between about 1000 nm and about 2000 nm.

Embodiment 6: The method of any of Embodiments 1 through 5, further comprising selecting the substrate to comprise a metal.

Embodiment 7: The method of any of Embodiments 1 through 6, further comprising selecting the component of the downhole tool to comprise a component of a bearing assembly having a first bearing member and a second bearing member.

Embodiment 8: The method of any of Embodiments 1 through 7, further comprising selecting the component of the downhole tool to comprise a cutting element.

Embodiment 9: The method of any of Embodiments 1 through 8, further comprising selecting the component of the downhole tool to comprise a component of a sealing assembly having at least one seal.

Embodiment 10: The method of any of Embodiments 1 through 9, further comprising selecting the component of the downhole tool to comprise a component of a motor having a stator and a rotor.

Embodiment 11: The method of any of Embodiments 1 through 10, further comprising selecting the component of the downhole tool to comprise at least one of a depth-of-cut control feature, a wear-resistant insert, or a wear pad.

Embodiment 12: The method of any of Embodiments 1 through 11, further comprising selecting the component of the downhole tool to comprise a component of a pump assembly having at least one impeller and at least one diffuser.

Embodiment 13: A downhole tool, comprising: a component of the downhole tool; and a volume of hard material comprising quenched carbon disposed on a surface of the component.

Embodiment 14: The downhole tool of Embodiment 13, wherein the volume of hard material comprising quenched carbon has a thickness of between about 1000 nm and about 2000 nm.

Embodiment 15: The downhole tool of Embodiment 13 or Embodiment 14, wherein the volume of hard material comprising quenched carbon has a hardness greater than diamond.

Embodiment 16: The downhole tool of any of Embodiments 13 through 15, wherein the component of the downhole tool comprises a cutting element.

Embodiment 17: The downhole tool of any of Embodiments 13 through 16, wherein the component of the downhole tool comprises a component of a bearing assembly having a first bearing member and a second bearing member.

Embodiment 18: The downhole tool of any of Embodiments 13 through 17, wherein the component of the downhole tool comprises a component of a sealing assembly having at least one seal.

Embodiment 19: The downhole tool of any of Embodiments 13 through 18, wherein the component of the downhole tool comprises a component of a motor having a stator and a rotor.

Embodiment 20: The downhole tool of any of Embodiments 13 through 19, wherein the component of the downhole tool comprises at least one of a depth-of-cut control feature, a wear-resistant insert, or a wear pad.

Embodiment 21: The downhole tool of any of Embodiments 13 through 20, wherein the component of the downhole tool comprises a component of a pump assembly having at least one impeller and at least one diffuser.

Embodiment 22: A bearing assembly of a downhole tool, comprising: a first bearing member, a second bearing member abutting against the first bearing member, the first bearing member and the second bearing member configured to rotationally slide against each other; and a volume of hard material comprising quenched carbon disposed on at least one of the first bearing member or the second bearing member.

Embodiment 23: The bearing assembly of Embodiment 22, wherein the volume of hard material comprising quenched carbon has a hardness greater than diamond.

Embodiment 24: A method of forming a polycrystalline compact, comprising: depositing a film of amorphous carbon on a substrate, irradiating the film of amorphous carbon to form liquid carbon in an undercooled state, quenching the liquid carbon to form diamond grains on the substrate at ambient pressures, and subjecting the diamond grains and a catalyst material to a high pressure, high temperature sintering process.

Embodiment 25: The method of Embodiment 24, further comprising selecting the substrate to comprise a substrate of a cutting element.

Embodiment 26: A downhole tool, comprising: a component of the downhole tool; and a polycrystalline compact comprising quenched carbon grains disposed on a surface of the component.

Embodiment 27: The downhole tool of Embodiment 26, wherein the component of the downhole tool comprises a cutting element.

While the present disclosure has been described herein with respect to certain illustrated embodiments, those of ordinary skill in the art will recognize and appreciate that it is not so limited. Rather, many additions, deletions, and modifications to the illustrated embodiments may be made without departing from the scope of the disclosure as hereinafter claimed, including legal equivalents thereof. In addition, features from one embodiment may be combined with features of another embodiment while still being encompassed within the scope of the disclosure as contemplated by the inventors.

1. A method of forming a volume of hard material on a component of a downhole tool, the method comprising:
depositing a film of amorphous carbon on a substrate, wherein the substrate comprises a component of a downhole tool;
irradiating the film of amorphous carbon to form liquid carbon in an undercooled state; and
quenching the liquid carbon to form a layer of quenched carbon on the substrate.

2. The method of claim 1, further comprising forming the layer of quenched carbon to a thickness of between about 1000 nm and about 2000 nm.

3. The method of claim 1, further comprising selecting the substrate to comprise a metal.

4. The method of claim 1, further comprising selecting the component of the downhole tool to comprise a cutting element.

5. The method of claim 1, further comprising selecting the component of the downhole tool to comprise a component of a bearing assembly having a first bearing member and a second bearing member.

6. The method of claim 1, further comprising selecting the component of the downhole tool to comprise a component of a sealing assembly having at least one seal.

7. The method of claim 1, further comprising selecting the component of the downhole tool to comprise a component of a motor having a stator and a rotor.

8. The method of claim 1, further comprising selecting the component of the downhole tool to comprise at least one of a depth-of-cut control feature, a wear-resistant insert, or a wear pad.

9. The method of claim 1, further comprising selecting the component of the downhole tool to comprise a component of a pump assembly having at least one impeller and at least one diffuser.

10. A downhole tool, comprising:
a component of the downhole tool; and
a volume of hard material comprising quenched carbon disposed on a surface of the component.

11. The downhole tool of claim 10, wherein the volume of hard material comprising quenched carbon has a thickness of between about 20 nm and about 2000 nm.

12. The downhole tool of claim 10, wherein the volume of hard material comprising quenched carbon has a hardness greater than diamond.

13. The downhole tool of claim 10, wherein the component of the downhole tool comprises at least one cutting element.

14. The downhole tool of claim 10, wherein the component of the downhole tool comprises a component of a bearing assembly having a first bearing member and a second bearing member.

15. The downhole tool of claim 10, wherein the component of the downhole tool comprises a component of a sealing assembly having at least one seal.

16. The downhole tool of claim 10, wherein the component of the downhole tool comprises a component of a motor having a stator and a rotor.

17. The downhole tool of claim 10, wherein the component of the downhole tool comprises at least one of a depth-of-cut control feature, a wear-resistant insert, or a wear pad.

18. The downhole tool of claim 10, wherein the component of the downhole tool comprises a component of a pump assembly having at least one impeller and at least one diffuser.

19. A downhole tool, comprising:
a component of the downhole tool; and
a polycrystalline compact comprising quenched carbon grains disposed on a surface of the component.

20. The downhole tool of claim 19, wherein the component of the downhole tool comprises a cutting element.
